(19) United States
(12) Patent Application Publication
(10) Pub. No.: US 2024/0381681 A1
(43) Pub. Date: Nov. 14, 2024

(54) ELECTRONIC APPARATUSES AND MANUFACTURING METHODS THEREOF

(71) Applicant: Shenzhen China Star Optoelectronics Semiconductor Display Technology Co., Ltd., Shenzhen (CN)

(72) Inventors: Zhiqing SHI, Shenzhen (CN); Jinyang ZHAO, Shenzhen (CN); Lixuan CHEN, Shenzhen (CN); Xuefei LI, Shenzhen (CN)

(73) Assignee: Shenzhen China Star Optoelectronics Semiconductor Display Technology Co., Ltd., Shenzhen (CN)

(21) Appl. No.: 18/533,229

(22) Filed: Dec. 8, 2023

(30) Foreign Application Priority Data
May 12, 2023 (CN) 202310542303.5

(51) Int. Cl. H10K 50/115; H10K 59/122; H10K 71/60

(52) U.S. Cl. CPC H10K 50/115; H10K 59/122; H10K 71/60; H10K 71/15

(57) ABSTRACT

The present disclosure discloses an electronic apparatus and manufacturing method thereof. The electronic apparatus includes a substrate, a first electrode member, and an electron transport film; the first electrode member is disposed on the substrate; the electron transport film is disposed on the first electrode member and includes nanoparticles provided with a first ligand having an electropositive property or an electronegative property.

### CROSS-REFERENCE TO RELATED APPLICATION

This application claims the priority to and benefit of Chinese Patent Application No. 202310542303.5, filed on May 12, 2023, the disclosure of which is incorporated herein by reference in its entirety.

### TECHNICAL FIELD

The present disclosure relates to the field of display technology, and in particular, to electronic apparatuses and manufacturing methods thereof.

### BACKGROUND

Quantum dots (QDs) are nanoscale semiconductor materials with quantum fluorescence effects, and can emit different colors of fluorescence under the excitation of electricity or light. Quantum dot materials can endow displays with a wider color gamut, allowing terminal displays to have more beautiful color performance, thus making quantum dot light-emitting diodes (QLEDs) gradually favored by the business community in the field of new display technology, due to the high color purity and good stability of quantum dot luminescence.

A hole transport layer, a quantum dot layer, and an electron transport layer are generally disposed in a stack form in the QLEDs. Processing methods for the electron transport layer include spin coating, evaporation plating, and inkjet printing. However, the spin coating and evaporation plating use more materials, leading to the increasing of cost; and it is difficult for the inkjet printing to achieve high resolution due to the limitation of process conditions.

### SUMMARY

Embodiments of the present disclosure provide an electronic apparatus, including:
a substrate;
a first electrode member disposed on the substrate; and
an electron transport film disposed on the first electrode member, in which the electron transport film includes nanoparticles, and the nanoparticles are provided with a first ligand having an electropositive property or an electronegative property.

Embodiments of the present disclosure further provide an electronic apparatus, including:
a substrate;
a pixel definition layer disposed on the substrate and provided with a pixel opening;
a first electrode members disposed on the substrate and in the pixel opening;
a quantum dot film disposed on the first electrode member and in the pixel opening; and
an electron transport film disposed on the quantum dot film and in the pixel opening, in which the electron transport film includes nanoparticles, and the nanoparticles are provided with a first ligand having an electropositive property or an electronegative property.

According to the above-mentioned purpose of the present disclosure, embodiments of the present disclosure further provide a manufacturing method of an electronic apparatus, including the following steps:
providing a substrate;
forming a first electrode member on the substrate; and
forming an electron transport film on the first electrode member, in which the electron transport film includes nanoparticles, and the nanoparticles are provided with a first ligand having an electropositive property or an electronegative property.

### BRIEF DESCRIPTION OF THE DRAWINGS

The following is a detailed description of the specific implementation methods of the present disclosure with reference to the attached drawings, which will make the technical solutions and other beneficial effects of the present disclosure obvious.

FIG. 1 is a schematic structural diagram of an electronic apparatus according to one or more embodiments of the present disclosure.

FIG. 2 is a plane actual rendering diagram of an electron transport film according to one or more embodiments of the present disclosure.

FIG. 3 is another schematic structural diagram of an electronic apparatus according to one or more embodiments of the present disclosure.

FIG. 4 is another schematic structural diagram of an electronic apparatus according to one or more embodiments of the present disclosure.

FIG. 5 is a flowchart of a manufacturing method of an electronic apparatus according to one or more embodiments of the present disclosure.

FIG. 6 and FIG. 7 are schematic structural diagrams of a manufacturing process of an electronic apparatus according to one or more embodiments of the present disclosure.

FIG. 8 and FIG. 9 are schematic structural diagrams of another manufacturing process of an electronic apparatus according to one or more embodiments of the present disclosure.

### DETAILED DESCRIPTION

The following will provide a clear and complete description of technical solutions in the embodiments of the present disclosure with reference to the attached drawings. Apparently, the described embodiments are only a part of the embodiments of the present disclosure, not all of them. Based on the embodiments in the present disclosure, all other embodiments obtained by those skilled in the art without creative labor fall within the scope of protection in the present disclosure.

The following disclosure provides many different embodiments or examples to implement different structures of the present disclosure. In order to simplify the disclosure of the present disclosure, specific embodiments of components and settings will be described below. It is clear that these are only examples and are not intended to limit the present disclosure. Moreover, the present disclosure may repeat reference numbers and/or reference letters in different embodiments for the purpose of simplification and clarity, and does not itself indicate the relationship between the various embodiments and/or settings discussed. Further, the present disclosure provides examples of various specific processes and materials, but ordinary skilled in the art may be aware of the application of other processes and/or the use of other materials.

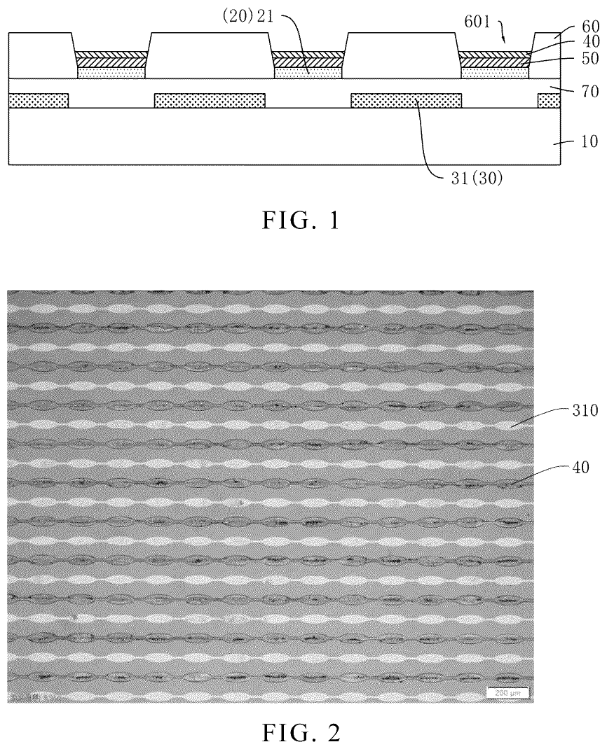

Referring to FIG. 1, the embodiments of the present disclosure provide an electronic apparatus that includes a substrate 10, a first electrode member 21, and an electron transport film 40.

The first electrode member 21 is disposed on the substrate 10. The electron transport film 40 is disposed on the first electrode member 21 and includes nanoparticles. The nanoparticles are provided with a first ligand having an electropositive property or an electronegative property.

In the application process, the present disclosure uses the nanoparticles containing the first ligand having the electropositive property or the electronegative property to form the electron transport film 40, so that an electric field can be formed between the first electrode member 21, and other electrode members in the panel or peripheral electrode members by applying a voltage thereto, allowing the nanoparticles to deposit on a surface of the first electrode member 21 under the action of an electric field force. Moreover, the shape and the area of the electron transport film 40 can be designed according to the shape and the area of the first electrode member 21, thereby realizing rapid deposition of the electron transport film 40 and high resolution of the electronic apparatus.

Specifically, referring to FIG. 1, in some embodiments of the present disclosure, the electronic apparatus includes a substrate 10, a second metal layer 30 disposed on the substrate 10, a spacing layer 70 covering the second metal layer 30, a first metal layer 20 and a pixel definition layer 60 disposed on the spacing layer 70, a quantum dot film 50 disposed on the first metal layer 20, and the electron transport film 40 disposed on the quantum dot film 50.

In some embodiments, the electronic apparatus provided by the embodiments of the present disclosure also includes thin-film transistor devices and signal lines disposed on the substrate 10, and a cathode layer and an encapsulation layer disposed on the electron transport film 40, which are not shown in the figures.

In some embodiments of the present disclosure, the first metal layer 20 includes a plurality of first electrode members 21, and the pixel definition layer 60 is provided with a plurality of pixel openings 601. Each of the pixel openings 601 is disposed corresponding to one first electrode member 21, and exposes an upper surface of the corresponding first electrode member 21.

Further, the quantum dot film 50 is disposed in the pixel opening 601 and disposed on the corresponding first electrode member 21, and the electron transport film 40 is disposed on a side of the quantum dot film 50 away from the first electrode member 21. In some embodiments, the electronic apparatus also includes a hole transport film disposed between the quantum dot film 50 and the first electrode member 21, which is not shown in the figures.

The second metal layer 30 includes a plurality of second electrode members 31, and the spacing layer 70 covers the plurality of second electrode members 31. Each of the second electrode members 31 is disposed between adjacent first electrode members 21, that is, an orthographic projection of each of the second electrode members 31 on the substrate 10 is disposed between orthographic projections of adjacent first electrode members 21 on the substrate 10. Thus, when a voltage is applied to the first electrode members 21 and the second electrode members 31, a horizontal electric field can be formed between the first electrode members 21 and the second electrode members 31.

In some embodiments, the second metal layer 30 is a metal film layer additionally disposed in the electronic apparatus of the present disclosure, so that the second electrode members 31 can be arranged in the second metal layer 30 at a pre-determined position, without being limited by the arrangement space, and without spatial conflicts with other devices in the electronic apparatus, and the second electrode members 31 can be arranged more evenly, making the electric field formed between the first electrode members 21 and the second electrode members 31 more well-distributed, thereby obtaining the electron transport film 40 with higher uniformity.

In some embodiments, the second metal layer 30 is an existing metal film layer in the electronic apparatus. For example, the second electrode members 31 are common voltage signal lines in the electronic apparatus. When the common voltage signal lines are multiplexed as the second electrode members 31, a horizontal electric field can be formed between the common voltage signal lines and the first electrode members 21.

In some embodiments of the present disclosure, the electron transport film 40 includes the nanoparticles provided with the first ligand having the electropositive property or the electronegative property, so that the nanoparticles have the electropositive property or the electronegative property as a whole. Thus, when a horizontal electric field is formed between the first electrode members 21 and the second electrode members 31 in the process, the nanoparticles can move under the action of the electric field force. Moreover, by designing the nanoparticles having the electrical property different from that of the first electrode members 21, the nanoparticles can be deposited on the first electrode members 21 to obtain the electron transport film 40.

In the embodiments of the present disclosure, the shape and the area of the first electrode members 21 exposed within the pixel openings 601 can be controlled to form the electron transport film 40 having the corresponding shape and area, thereby realizing high resolution of the electronic apparatus.

In some embodiments the nanoparticles include at least one of zinc oxide, zirconia, and silicon oxide, and the first ligand includes a group containing a carboxylate ion or a group containing an ammonium ion.

Moreover, the quantum dot film 50 is disposed between the first electrode member 21 and the electron transport film 40. In some embodiments of the present disclosure, the quantum dot film 50 includes quantum dots provided with a second ligand having an electropositive property or an electronegative property, so that a voltage can be applied to the first electrode member 21 and the second electrode member 31 when the quantum dot film 50 is formed, thus, the quantum dots can be deposited on the first electrode member 21 to form the quantum dot film 50 under the action of the electric field force, and then the nanoparticles are deposited on the quantum dot film 50 to form the electron transport film 40.

In some embodiments, the first ligand has an electrical property different from or has the same electrical property as that of the second ligand. When the quantum dots are deposited, the first electrode member 21 has the electrical property different from the second ligand; and when the nanoparticles are deposited, the first electrode member 21 has the same electrical property as the first ligand.

Referring to FIG. 1 and FIG. 2, FIG. 2 is a plane actual rendering of the electron transport film 40 of the electronic apparatus provided by the embodiments of the present disclosure. An electrode area 310 represents an area where the second electrode member 31 is disposed, and the first electrode member 21 is disposed below the electron transport film 40. A row of electrode areas 310 are provided between adjacent rows of electron transport films 40, and a row of electron transport films 40 are disposed between adjacent two rows of electrode areas 310.

It can be understood that, the shape of the electrode area 310 is not limited in the embodiments of the present disclosure. The shape of the second electrode member 31 may match the shape of the electrode area 310, for example, elliptical, circular, polygonal, or the like.

In the context, the present disclosure uses the nanoparticles containing the first ligand having the electropositive property or the electronegative property to form the electron transport film 40, so that an electric field can be formed between the first electrode member 21, and other electrode members in the panel or peripheral electrode members by applying a voltage thereto, allowing the nanoparticles to deposit on a surface of the first electrode member 21 under the action of an electric field force. Moreover, the shape and the area of the electron transport film 40 can be designed according to the shape and the area of the first electrode member 21, thereby realizing rapid deposition of the electron transport film 40 and high resolution of the electronic apparatus.

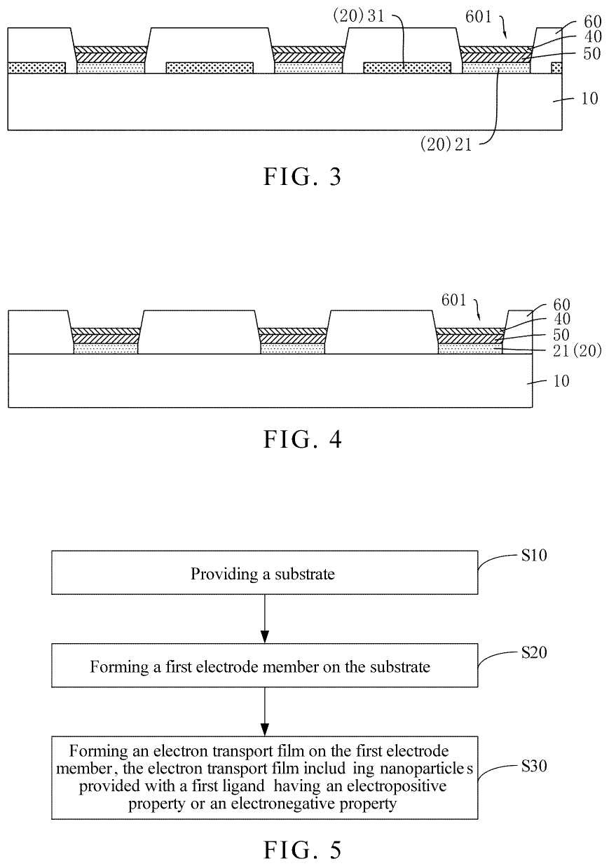

Referring to FIG. 3, other embodiments of the present disclosure are different from the previously mentioned embodiments in that a setting position of the second electrode members 31 are different.

In these embodiments, the first metal layer 20 includes a plurality of first electrode members 21 and a plurality of second electrode members 31, and each of the first electrode members 21 and each of the second electrode members 31 are disposed at intervals. Each of the first electrode members 21 is disposed corresponding to one of the pixel openings 601, and each of the second electrode members 31 is disposed between adjacent two pixel openings 601, so that a horizontal electric field can be formed between the first electrode members 21 and the second electrode members 31, and the nanoparticles provided with the positively charged or negatively charged first ligand can be quickly deposited on the first electrode members 21 to form the electron transport film 40.

Compared to the previously mentioned embodiments, the second electrode members 31 and the first electrode members 21 in the embodiments, as illustrated in FIG. 3, can be formed in the same metal film layer and using the same mask, which further simplifies the process and reduces cost of the process.

Referring to FIG. 4, some embodiments of the present disclosure are different from the embodiments as illustrated in FIG. 1 in that the electronic apparatus is not provided with the second electrode members.

Specifically, in the process of the electronic apparatus in the embodiments as illustrated in FIG. 4, an additional electrode member may be disposed on a side of the pixel definition layer 60 away from the substrate 10, and a voltage can be applied to the first electrode member 21 and the additional electrode member to form a vertical electric field between the first electrode member 21 and the additional electrode member, so that the nanoparticles provided with the first ligand can be deposited on the first electrode member 21 under the action of the vertical electric field to obtain the electron transport film 40.

Compared to the embodiments as illustrated in FIG. 1, it is not necessary to additionally set electrode members in the electronic apparatus provided by the embodiments as illustrated in FIG. 4. Moreover, a vertical electric field can be formed between the external additional electrode member and the first electrode member 21, so that the nanoparticles can move and be deposited on the first electrode member 21, which can simplify the process of the electronic apparatus.

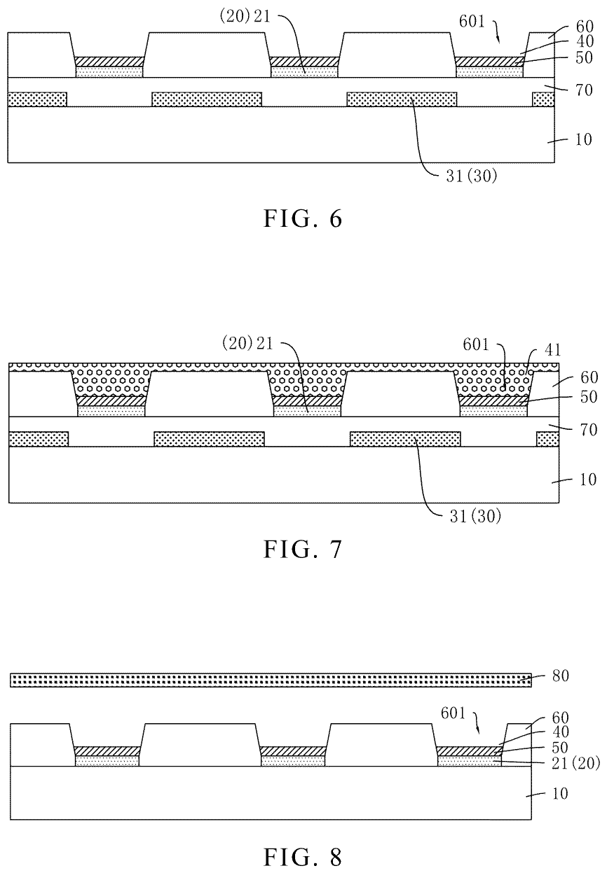

In addition, embodiments of the present disclosure further provide a manufacturing method of an electronic apparatus. Referring to FIG. 1, FIG. 5, FIG. 6, and FIG. 7, in some embodiments of the present disclosure, the manufacturing method of the electronic apparatus includes the following step S10, step S20, and step S30.

In step S10, the substrate 10 is provided.

In step S10, the second metal layer 30 is formed on the substrate 10 and patterned to obtain a plurality of second electrode members 31; then, the spacing layer 70 covering the plurality of second electrode members 31 is formed.

In step S20, a plurality of first electrode members 21 are formed on the substrate 10.

In step S20, the first metal layer 20 is formed on the spacing layer 70 and patterned to obtain the plurality of first electrode members 21. The orthographic projection of each of the first electrode members 21 on the substrate 10 is disposed between orthographic projections of adjacent two second electrode members 31 on the substrate 10.

The pixel definition layer 60 is formed on the spacing layer 70 and patterned to obtain a plurality of pixel openings 601. Each of the pixel openings 601 is disposed corresponding to one of the first electrode members 21, and exposes an upper surface of the corresponding first electrode member 21, as shown in FIG. 6.

A quantum dot solution is provided. The quantum dot solution includes the quantum dots provided with the second ligand having the electropositive property or the electronegative property.

A voltage can be applied to the first electrode member 21 and the second electrode member 31 to form a horizontal electric field between the first electrode member 21 and the second electrode member 31, and the first electrode member 21 has the electrical property different from that of the second ligand, so that the quantum dots can be deposited on the first electrode member 21 to form the quantum dot film 50.

In step S30, the electron transport film 40 is formed on the first electrode member 21. The electron transport film 40 includes the nanoparticles provided with the first ligand having the electropositive property or the electronegative property.

In step S30, an intermediate is formed on the nanoparticles.

The nanoparticles are added into a solvent to form an electron transport material 41, as shown in FIG. 7. The intermediate is dissociated to form the first ligand having the electropositive property or the electronegative property.

The electron transport material 41 is placed on the substrate 10, and then a voltage is applied to the first electrode member 21 and the second electrode member 31 to form an electric field, so that the nanoparticles can be deposited on the first electrode member 21 to form the electron transport film 40.

Optionally, the nanoparticles include at least one of zinc oxide, zirconia, and silicon oxide, and the first ligand includes a group containing a carboxylate ion or a group containing an ammonium ion. The nanoparticles being zinc oxide and the first ligand being a group containing a carboxylate ion is taken as an example for illustrating some embodiments of the present disclosure.

Specifically, a certain amount of anhydrous ethanol can be added to a first container, and heated to 80° C. under magnetic stirring. Then, a certain amount of a first dispersant and modifier are added to the first container until the first dispersant and the modifier are completely dissolved. Zinc salt is slowly added to the first container, and the reaction solution is reacted for 30 minutes; then reaction product is poured into a second container, stood, and precipitated, and treated using a centrifuge and dried to obtain a zinc oxide powder.

Finally, the zinc oxide powder and a second dispersant are added to a solvent of propylene glycol methyl ether acetate (PGMEA) to obtain a zinc oxide dispersion, which is the electron transport material 41 containing the zinc oxide as the above-mentioned nanoparticles.

The zinc oxide powder can be prepared according to conventional processes, which will not be repeated here. In some embodiments, the second dispersant includes at least one of anionic dispersants such as ammonium polyacrylate and sodium dodecylbenzenesulfonate.

Optionally, a mass percentage of the nanoparticles in the electron transport material 41 is greater than or equal to 0.1% and less than or equal to 50%, and a concentration of the nanoparticles in the electron transport material 41 ranges from 0.1 mg/mL to 500 mg/mL. In some embodiments, a mass percentage of the second dispersant in the electron transport material 41 is greater than or equal to 0.01% and less than or equal to 50%.

In some embodiments, the modifier is carboxyl polyethylene glycol silane to modify the nanoparticles, so as to form the intermediate that has a group containing a carboxyl group.

In some embodiments, the solvent for forming the electron transport material 41 includes propylene glycol methyl ether acetate. When the nanoparticles provided with an intermediate is dissolved in the propylene glycol methyl ether acetate, the intermediate is dissociated to form a carboxylate ion, which is the first ligand having the electronegative property, making the entirety containing the nanoparticles and the first ligand have the electronegative property as a whole.

Then, the electron transport material 41 is placed on the substrate 10, and a voltage is applied to the first electrode member 21 and the second electrode member 31 to form an electric field. The first electrode member 21 has the electropositive property and the second electrode member 31 has the electronegative property, so that the nanoparticles can be deposited on the first electrode member 21 to form the electron transport film 40.

In some embodiments, the intensity of the electric field formed between the first electrode member 21 and the second electrode member 31 ranges from 5×10⁵ to 4×10⁷ V/m, and the deposition time of the nanoparticles ranges from 1 to 3600 s.

In some embodiments, the modifier is amino polyethylene glycol silane, and the corresponding first ligand is a group containing an ammonium ion, making the first ligand has the electropositive property thus, the entirety containing the nanoparticles and the first ligand presents the electropositive property. Moreover, when a voltage is applied to the first electrode member 21 and the second electrode member 31 to form an electric field, the first electrode member 21 has the electronegative property, while the second electrode member 31 has the electropositive property, so that the nanoparticles can be deposited on the first electrode member 21, then the solvent is removed by heating to form the electron transport film 40.

It can be understood that, in some embodiments of the present disclosure, the electron transport film 40 is formed on a side of the quantum dot film 50 away from the first electrode member 21, and the quantum dot film 50 and the electron transport film 40 are sequentially formed by electrophoresis.

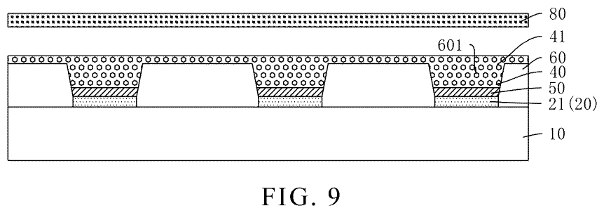

Referring to FIG. 3, FIG. 8, and FIG. 9, a manufacturing method of the electronic apparatus in some embodiments of the present disclosure is different from the above-mentioned embodiments in that:
in step S10, the second metal layer 30 is not needed to be formed on the substrate 10, that is, it is not necessary to set the second electrode members 31 in the electronic apparatus;
in step S30, an additional electrode member 80 is formed on a side of the pixel definition layer 60 away from the substrate 10, as shown in FIG. 8. Then, the electron transport material 41 is added between the pixel definition layer 60 and the additional electrode member 80, as shown in FIG. 9; and
subsequently, a voltage can be applied to the first electrode member 21 and the additional electrode member 80 to form a vertical electric field between the first electrode member 21 and the additional electrode member 80, so that the nanoparticles in the electron transport material 41 can move and be deposited on the first electrode member 21 under the action of the electric field force, and then the solvent is removed to form the electron transport film 40.

In the context, in the embodiments of the present disclosure, by modifying the nanoparticles to form the first ligand having the electropositive property or the electronegative property on the nanoparticles, then forming an electric field between the first electrode member 21, and the second electrode member 31 or the additional electrode member 80 to drive the movement of the nanoparticles, further, controlling the first electrode member 21 having the electrical property different from that of the first ligand, so that the nanoparticles can be deposited on the first electrode member 21 to obtain the electron transport film 40. Moreover, the shape and the area of the electron transport film 40 can be designed according to the shape and the area of the first electrode member 21, thereby realizing rapid deposition of the electron transport film 40 and high resolution of the electronic apparatus.

In the embodiments of the present disclosure, the electronic apparatus may include a device such as a display panel, a solar cell, or the like, which is not limited here.

In the above-mentioned embodiments, the description of each embodiment has its own emphasis. For the parts that are not detailed in one embodiment, please refer to the relevant descriptions of other embodiments.

The electronic apparatus and the manufacturing method thereof provided by the embodiments of the present disclosure are described in detail. In this context, specific embodiments are adopted to illustrate a principle and implementation modes of the present disclosure. The description of the above-mentioned embodiments is only used to help understand a core idea of the present disclosure. Ordinary skilled in the art should understand that they can still modify the technical solutions described in the aforementioned embodiments, or equivalently replace some of the technical features; and these modifications or substitutions do not separate the essence of the corresponding technical solutions from the scope of the technical solutions in various embodiments of the present disclosure.

What is claimed is:

1. An electronic apparatus comprising:
a substrate;
a first electrode member disposed on the substrate; and
an electron transport film disposed on the first electrode member, wherein the electron transport film comprises nanoparticles, wherein the nanoparticles are provided with a first ligand having an electropositive property or an electronegative property.

2. The electronic apparatus of claim 1, wherein the nanoparticles comprise at least one of zinc oxide, zirconia, and silicon oxide, and the first ligand comprises a group containing a carboxylate ion or a group containing an ammonium ion.

3. The electronic apparatus of claim 1, wherein the electronic apparatus comprises a first metal layer and a pixel definition layer disposed on the substrate, and the pixel definition layer is provided with a pixel opening; and
wherein the first metal layer comprises the first electrode member, the pixel opening is disposed corresponding to the first electrode member, and the electron transport film is disposed on a side of the first electrode member away from the substrate.

4. The electronic apparatus of claim 3, wherein the electronic apparatus further comprises a second metal layer disposed on a side of the first metal layer away from or close to the substrate,
wherein the second metal layer comprises a second electrode member, an orthographic projection of the second electrode member on the substrate is disposed between orthographic projections of adjacent first electrode members on the substrate, and the second electrode member is configured to form an electric field with the adjacent first electrode members.

5. The electronic apparatus of claim 3, wherein the first metal layer further comprises a second electrode member disposed between adjacent pixel openings, and configured to form an electric field with the first electrode member.

6. The electronic apparatus of claim 3, wherein the electronic apparatus further comprises a quantum dot film disposed in the pixel opening and between the first electrode member and the electron transport film;
wherein the quantum dot film comprises quantum dots, and the quantum dots are provided with a second ligand having an electropositive property or an electronegative property.

7. The electronic apparatus of claim 6, wherein the first ligand has an electrical property different from that of the second ligand.

8. An electronic apparatus comprising:
a substrate;
a pixel definition layer disposed on the substrate and provided with a pixel opening;
a first electrode members disposed on the substrate and in the pixel opening;
a quantum dot film disposed on the first electrode member and in the pixel opening; and
an electron transport film disposed on the quantum dot film and in the pixel opening, wherein the electron transport film comprises nanoparticles, wherein the nanoparticles are provided with a first ligand having an electropositive property or an electronegative property.

9. The electronic apparatus of claim 8, wherein the nanoparticles comprise at least one of zinc oxide, zirconia, and silicon oxide, and the first ligand comprises a group containing a carboxylate ion or a group containing an ammonium ion.

10. The electronic apparatus of claim 8, wherein the electronic apparatus further comprises a second electrode member, wherein an orthographic projection of the second electrode member on the substrate is disposed between orthographic projections of adjacent first electrode members on the substrate, and the second electrode member is configured to form an electric field with the adjacent first electrode members.

11. The electronic apparatus of claim 8, wherein the electronic apparatus further comprises a first metal layer disposed on the substrate, wherein the first metal layer comprises the first electrode member and a second electrode member, and the second electrode member is disposed between adjacent pixel openings and configured to form an electric field with first electrode members in the adjacent pixel openings.

12. The electronic apparatus of claim 8, wherein the electronic apparatus further comprises a first metal layer disposed on the substrate, wherein the first metal layer comprises the first electrode member and a second electrode member, an orthographic projection of the second electrode member on the substrate is disposed between orthographic projections of adjacent first electrode members on the substrate, and the second electrode member is configured to form an electric field with the adjacent first electrode members.

13. The electronic apparatus of claim 8, wherein the electronic apparatus further comprises:
a first metal layer comprising the first electrode member; and
a second metal layer disposed on a side of the first metal layer away from or close to the substrate, wherein the second metal layer comprises a second electrode member, an orthographic projection of the second electrode member on the substrate is disposed between orthographic projections of adjacent first electrode members on the substrate, and the second electrode member is configured to form an electric field with the adjacent first electrode members.

14. The electronic apparatus of claim 8, wherein the quantum dot film comprises quantum dots, and the quantum dots are provided with a second ligand having an electropositive property or an electronegative property.

15. The electronic apparatus of claim 14, wherein the first ligand has an electrical property different from that of the second ligand.

16. A manufacturing method of an electronic apparatus comprising following steps:
providing a substrate;
forming a first electrode member on the substrate; and
forming an electron transport film on the first electrode member, wherein the electron transport film comprises nanoparticles, and the nanoparticles are provided with a first ligand having an electropositive property or an electronegative property.

17. The manufacturing method of the electronic apparatus of claim 16, wherein the step of forming the first electrode member on the substrate comprises:
forming the first electrode member and a second electrode member disposed at intervals on the substrate; or
forming an additional electrode member on a side of the first electrode member away from the substrate.

18. The manufacturing method of the electronic apparatus of claim 17, wherein the step of forming the electron transport film on the first electrode comprises:
forming an intermediate on the nanoparticles;
adding the nanoparticles to a solvent to form an electron transport material, wherein the intermediate is dissociated in the solvent to form the first ligand having the electropositive property or the electronegative property; and
placing the electron transport material on the substrate, and applying a voltage to the first electrode member and the second electrode member to form an electric field, or applying a voltage to the first electrode member and the additional electrode member to form an electric field, enabling the nanoparticles to deposit on the first electrode member to form the electron transport film.

19. The manufacturing method of the electronic apparatus of claim 18, wherein the nanoparticles comprise at least one of zinc oxide, zirconia, and silicon oxide, the intermediate comprises a carboxyl group or amino group, and the first ligand comprises a group containing a carboxylate ion or a group containing an ammonium ion.

20. The manufacturing method of the electronic apparatus of claim 18, wherein a mass percentage of the nanoparticles in the electron transport material is greater than or equal to 0.1% and less than or equal to 50%.
